(19) United States
(12) Patent Application Publication
(10) Pub. No.: US 2017/0082873 A1
(43) Pub. Date: Mar. 23, 2017

(54) HIGH FREQUENCY LIGHT EMISSION DEVICE

(71) Applicant: Brown University, Providence, RI (US)

(72) Inventors: Rashid Zia, Providence, RI (US); Sebastien Cueff, Ecully (FR); Sinan Karaveli, Boston, MA (US)

(73) Assignee: Brown University, Providence, RI (US)

(21) Appl. No.: 14/668,327

(22) Filed: Mar. 25, 2015

Related U.S. Application Data
(60) Provisional application No. 61/970,234, filed on Mar. 25, 2014.

(51) Int. Cl. G02F 1/01; G02F 1/00; H04B 10/50; H01L 33/58; H01L 33/60

(52) U.S. Cl. CPC G02F 1/0115; H01L 33/58; H01L 33/60; H04B 10/502; G02F 1/011; G02F 1/0018; G02F 2201/34; G02F 2203/50

(57) ABSTRACT

Systems, apparatuses, and methods for modulating light at high frequencies by addressing the issue of direct modulation of long lifetime light emitters. Dynamic control of the local density of optical states (LDOS) to exploit the differences between electric and magnetic dipole transitions allows for higher frequency modulation. The LDOS is controlled, in part, by designing a structure such that it enhances or suppresses electric and magnetic dipoles. Direct modulation may be achieved by designing the optical environment to adjust the interferences between the emitted light field and its own reflection at the emitter's location. The optical environment may include light emission material, switchable material, spacer materials, and reflective materials. The structures creating the optical environment enable a new nanometer-scale architecture for on-chip ultrafast directly modulated light sources, which could be easily integrated locally on a range of nanoelectronic and nanophotonic structures, along with light-emitting diodes, waveguides, and fiber optics.

### CROSS REFERENCE TO RELATED APPLICATIONS

The application claims priority to U.S. Provisional Application Ser. No. 61/970,234, titled “HIGH FREQUENCY LIGHT EMISSION DEVICE,” which is incorporated herein by reference in its entirety.

### STATEMENT REGARDING FEDERALLY SPONSORED RESEARCH OR DEVELOPMENT

This invention was made with government support under ECCS-0846466 and awarded by the National Science Foundation and FA9550-10-1-0026 awarded by the Air Force Office of Sponsored Research. The government has certain rights in the invention.

### TECHNICAL FIELD

The present disclosure provides a light emission device that can be directly modulated at a very high rate of speed. The device has a number of applications including, but not limited to, applications in optical data transmission. Related methods are also provided.

### INTRODUCTION

Direct modulation of light emission is usually believed to be limited by the intrinsic spontaneous emission rate of a light emitter. Indeed, when one pumps the electronic system governing light emission from such a quantum emitter, the rate at which light can be modulated (alternating from ‘ON’ and ‘OFF’ states) is limited by the lifetime of emission. For example, the lifetime of Er³⁺ is longer than 1 ms, imposing an upper bound for the ‘electronic’ modulation at 1 kHz. Such a rate is too slow to be used for any communication or data processing applications. Conventional modulation of light uses a light source and an optical modulator which are spatially separated. Such a two-step two devices scheme requires a large footprint (generally hundreds of μm²) which makes it challenging for future scalability at the nanoscale; it also constitutes a low efficiency system as much of the light must be “thrown out” in the modulation process.

### SUMMARY

This invention addresses the issue of direct modulation of long lifetime light emitters. The present invention enables one to realize new nanometer-scale architecture for on-chip ultrafast directly modulated light sources, which could be easily integrated locally on a range of nanoelectronic and nanophotonic structures. Additional structures, such as light-emitting diodes, waveguides, and fibers for use in fiber optic communication are also available. For example, direct, electrical, sub-lifetime modulation of light emission has direct applications at the interface of communication, display, and lighting technologies as well as in biological and chemical sensing.

In a first aspect, the present disclosure is directed to a multilayer thin film optical stack comprising: a light-emitting layer; and a switchable material layer, wherein light emission from the light-emitting layer is modulated based on the switchable material layer changing from a first state to a second state.

In a second aspect, the present disclosure is directed to a method of optical data transmission, the method comprising tuning an optical response of a switchable layer located adjacent a light-emitting layer, wherein light emitted from the light-emitting layer is modulated at a frequency higher than that of an inverse of the spontaneous emission rate of material comprising the light-emitting layer.

In a third aspect, the present disclosure is directed to an apparatus comprising: a light emitting erbium doped yttrium oxide (E³⁺:Y₂O₃) layer, wherein the light emitting Er³⁺:Y₂O₃ layer is about 10-100 nm thick; a spacer layer positioned above the light-emitting layer, wherein the spacer layer is about 80-100 nm thick; a vanadium dioxide (VO₂) phase change layer positioned above the spacer layer, wherein the VO₂ phase change layer is about 110-160 nm thick; and a reflective layer positioned above the VO₂ phase change layer, wherein light emission from the light emitting Er³⁺:Y₂ aver is modulated based on the VO₂ phase change layer changing from a first state to a second state.

### BRIEF DESCRIPTION OF THE FIGURES

FIG. 1 is a two-dimensional schematic view of an embodiment of a thin film light emitter according to the principles of the present disclosure;

FIG. 2 is a schematic view of another embodiment of a thin film light emitter according to the principles of the present disclosure;

FIG. 3 is a schematic view of a light-emitting waveguide according to the principles of the present disclosure; and

FIG. 4 is a schematic view of a multicomponent optical fiber according to the principles of the present disclosure.

### DETAILED DESCRIPTION

As mentioned above, the long lifetimes of certain light emitters, such as lanthanide and transition-metal phosphors or emitters, present challenges for conventional pump-based modulation methods where the maximum switching speeds are limited by the decay time of the excited state. While these light emitters have longer lifetimes, they are also efficient light emitters and often play a role in a range of modern device technologies from displays and lighting to lasers, sensors, and telecommunication. Nevertheless, their slow radiative decay rate is generally perceived as a technological limit for high-speed photonic devices. This is particularly problematic for transition-metal and lanthanide phosphors, such as erbium-doped materials, as they have lifetimes on the order of milliseconds to hundreds of microseconds, which would appear to restrict modulation speeds to the range of 1-10 kHz. To overcome this limit, the present application discloses methods and systems for directly modulating the light emitters at much higher frequencies. More specifically, the methods and systems dynamically control the local density of optical states (LDOS) to exploit the differences between electric and magnetic dipole transitions. The LDOS is controlled, in part, by designing a structure such that it enhances or suppresses electric and magnetic dipoles. The structure could be a cavity, resonator, waveguide, or similar structure. With materials that have magnetic dipole transitions, such as lanthanides and transition metals, direct modulation of the light emission may be controlled.

In one embodiment, the direct modulation may be achieved by designing the optical environment to adjust the interferences between the emitted light field and its own reflection at the emitter's location. The optical environment includes a light emission source, such as a lanthanide-emitter-doped (e.g. europium, holmium, neodymium, samarium, terbium, ytterbium etc.); or a transition-metal-doped (e.g. cobalt, chromium, nickel, iron, magnesium, and titanium) glass or crystal host (including e.g. fluorides such as MgF₂, NaYF₄, oxides such as MgO, SiO₂, SiOₓ, Y₂O₃, YVO₄, Y₃Al₅O₁₂, nitrides such as Si₃N₄ and SiNₓ, oxynitrides such as SiOₓN_{y}, phosphates such as P₂O₅). The light emission material may also have an intrinsic non-zero magnetic dipole transition. The optical environment also includes a switchable material. Such switchable materials are those materials that can be switched from one state to another, where switching causes an active modification of the refractive index of the material. One example of a switchable material would be a phase-change material, such as vanadium dioxide (VO₂) or chalcogenide materials (e.g. GeSbTe, GaLaS, etc.). Ferroelectric materials, such as ferroelectric oxides (e.g. LiNbO₃, BaTiO₃, PbZrTiO, etc.), may also be utilized as a switchable material. The switchable materials may be switched or changed via electrical energy, optical energy (such as from a laser), heat, and/or mechanical energy. Other materials and layers may also be included in the optical environment, such as spacer materials and reflective materials, as will be discussed below with reference to the figures.

By manipulating the optical environment, direct modulation of the light-emitting material may be achieved. For instance, the state of the switchable material may be switched or changed, causing modulation of the light-emitting material. The modulation occurs by enhancing the electric dipole transitions or the magnetic dipole transitions. In some embodiments, when the switchable material is in a particular state, the electric dipole transitions of the light-emitting material are enhanced and favored. When the switchable material is in a different state, the magnetic dipole transitions of the light-emitting material are enhanced and favored. When the magnetic dipole transitions are being enhanced, the electric dipole transitions may also be suppressed. The inverse may also occur: when the electric dipole transitions are enhanced, the magnetic dipole transitions may be suppressed. By being able to control whether the transitions are primarily magnetic dipole transitions or electric dipole transitions, the light emission from the light-emitting material can be effectively modulated. Through this direct modulation of the light emission, the wavelength, polarity, and direction of the light emission can all be controlled and modulated.

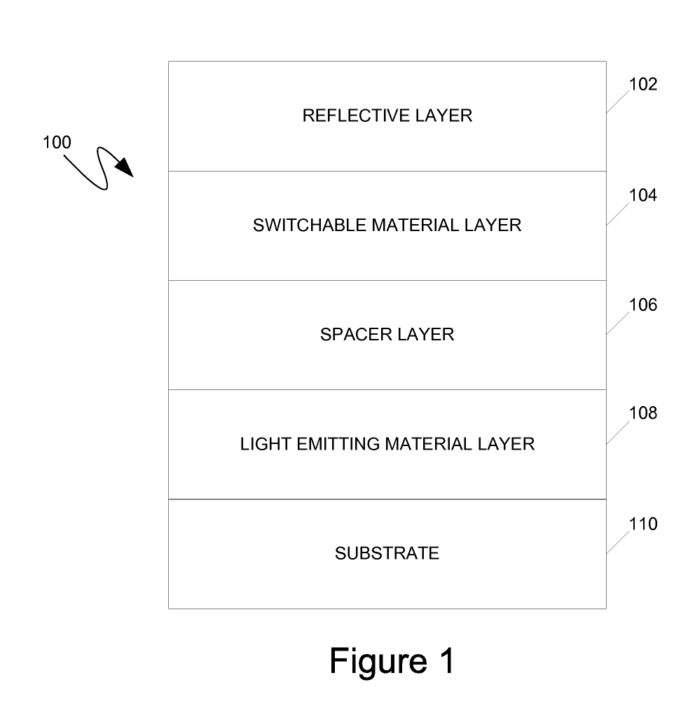

FIG. 1 depicts a two-dimensional view of one embodiment of a multilayer thin film optical stack 100. As shown in FIG. 1, the multi-layer optical stack includes a reflective layer 102, a switchable material layer 104, a spacer layer 106, a light-emitting material layer 108, and a substrate 110. Depending on the particular application, some of the layers may be optional, such as the spacer layer 106 and the reflective layer 102. In an embodiment, the light-emitting material layer 108 is an erbium doped yttrium oxide (Er³⁺:Y₂O₃) or any of the other types of light-emitting materials. The spacer layer 106 may be any material that has a low absorption rate for the desired wavelength of light to be used in the application. In embodiments using Er³⁺:Y₂O₃ as a light-emitting material, the desired wavelength of light may be in the infrared range for use in telecommunications applications. In those embodiments, the spacer layer 106 is a material that is substantially transparent in the infrared or near infrared range. Those materials could include materials such as TiO₂, Si, Si₃N₄, SiO₂, Al₂O₃, Y₂O₃, ITO, etc. In some applications, the spacer layer 106 may not be necessary. The switchable material layer 104 may be any type of the switchable material as described above. The reflective layer 102 may be a reflective metallic material such as Au, Ag, Al, etc. The reflective layer 102 may also be a multilayer of dielectric materials. Such a multilayer dielectric material may form a Distributed Bragg Reflector. Depending on the application, the reflective layer 102 may not be necessary. The substrate layer 110 is application dependent, and may have little effect on the actual light modulation. For example, the substrate layer 110 may be a quartz material to serve as a substrate and still observe light emitted from the light-emitting layer 108. Silicon substrates may also be used.

One main element to realizing modulation is to design the structure such that the state of the phase-change layer has maximum influence on the LDOS of the emitter layer 108. For example, a simple design to achieve this goal is a quarter-wavelength insulator-to-metal phase-change layer (i.e. thickness d=lambda/(4*n) where n is the refractive index and lambda is the free-space wavelength) located between an emitter layer 108 and a metal mirror, such as the reflective layer 102. If a multilayer stack is constructed in this way, there is a pi phase shift in the effective optical path length when the phase-change material is switched from the insulating to metallic state, which maximizes the influence of the phase-change on the surrounding LDOS. To confirm this effect, and also to design other structures that maximize the influence of the phase-change material on the LDOS for electric dipole and magnetic dipole transitions, the electric and magnetic LDOS can be calculated by the methods described in the Supplementary Information of Taminiau et al. “Quantifying the magnetic nature of light emission”, Nature Communications, volume 3, article number 979 (2012), doi:10.1038/ncomms1984, which is incorporated by reference in its entirety herein. The design can further be refined by numerical optimization of changes in the branching ratio of electric dipole and magnetic dipole transitions upon phase-change using the electric and magnetic LDOS together with the spectrally-resolved spontaneous emission rates. Such numerical optimization can also be used to achieve desired modifications, for example, within specific spectral bands for telecommunication.

In a particular embodiment of the optical stack depicted in FIG. 1, the substrate layer 110 is a quartz material, the light emitting material layer 108 is an erbium doped yttrium oxide (Er³⁺:Y₂O₃), the spacer layer 106 is TiO₂, the switchable material layer 104 is vanadium dioxide (VO₂), and the reflective layer 102 is silver (Ag). In a more specific embodiment, the spacer layer 106 is 80-100 nm thick, the switchable material layer 104 is 110-160 nm, and the light-emitting material layer 108 is 10-100 nm thick.

With the optical stack 100 depicted in FIG. 1, direct modulation of the light-emitting material may be achieved by switching the switchable material at a desired rate. By changing the state of the switchable material, the electric dipoles are favored for one state, and magnetic dipole transitions are favored for another state. For example, in an embodiment where the light-emitting layer 108 is erbium doped yttrium oxide (Er³⁺:Y₂O₃) and the switchable material is vanadium dioxide (VO₂), when the VO₂ is in an insulating state, the light-emitting layer 108 has a high magnetic local density of optical states. When the VO₂ is in a metallic state, the light-emitting layer 108 switches to a high electric local density of optical states. In the particular geometry described above, the Er³⁺ emission at 1536 nm can be tuned from approximately 70% magnetic dipole to about 80% electric dipole by changing the phase of VO₂. The spectrum of emitting light may also differ between magnetic dipole transitions and electric dipole transitions. The switching rate of these materials can be very fast, potentially at femtosecond ranges. As such, the direct modulation of the light-emitting layer is substantially higher than is possible by standard spontaneous emission, which has a lifetime of approximately 1 ms for erbium.

To create the phase change of the VO₂ (or other potential switchable materials), in embodiments, the phase change is triggered via modulated laser light. By controlling the frequency of the modulation of the laser light, the rate of the phase-change of the VO₂ can be controlled. For instance, the modulation of the laser light may be controlled by an acousto-optic modulator or any other mechanism to modulate the signal. Where Er³⁺:Y₂O₃ is used as a light-emitting material, a 1064 nm laser may be used to cause the phase change of the VO₂ because the 1064 nm wavelength light does not substantially interact with Er³⁺:Y₂O₃. A separate laser may be used to excite the Er³⁺:Y₂O₃. For example, a 532 nm laser may be used to excite the Er³⁺:Y₂O₃. In another embodiment, a single laser could be used to both excite the Er³⁺:Y₂O₃ and cause the phase-change of the VO₂. By changing the intensity of the single laser, the rate of the phase-change is controlled. The single laser may be a 980 nm laser.

In another embodiment, the switchable material is be switched electrically, rather than optically. For example, by applying an electric field to the switchable material layer 104, the material in the switchable layer 104 changes state. Depending on the type of switchable material, the electric field may cause a current to flow through the material. By controlling and modulating the electric field, the rate of the switching of the switchable material may be controlled in a substantially similar way as the optical switching performed by the laser(s), as described above. Both the optical and electrical control embodiments are used to tune the optical response of the switchable material. Either method may be used to modulate light emission at speeds substantially higher than available by modulating light emission based on the spontaneous emission rate of the light-emitting material.

Optical control may be favorable in places where geometrical or other constraints prevent or increase the complexity of having electrical inputs. For instance, within a fiber, it is often simpler to have optical inputs rather than electrical inputs.

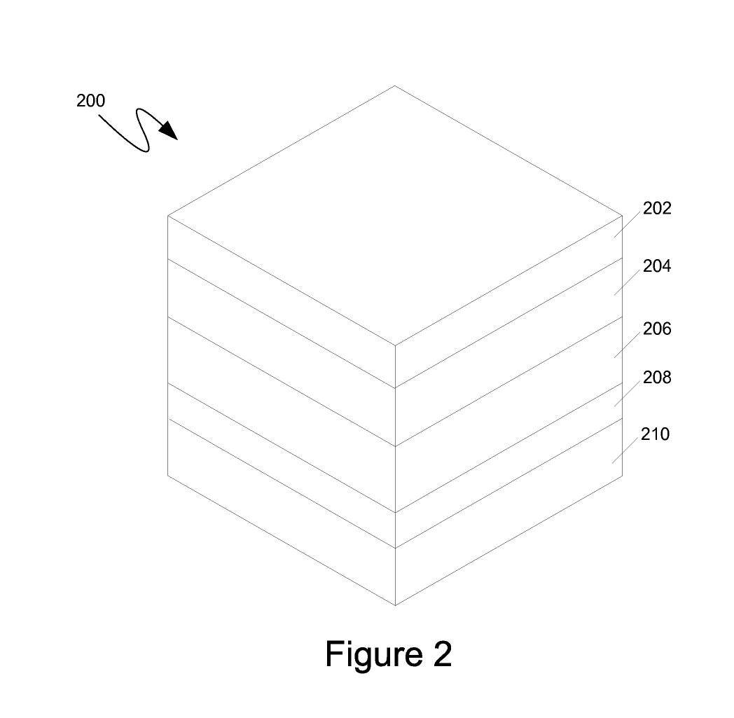

FIG. 2 depicts an embodiment of a light-emitting optical stack 200 where the switching of the switchable material layer 204 is controlled via electric fields. As depicted in FIG. 2, the base layer is a semiconductor layer 210. Above the semiconductor layer 210, is a light-emitting layer 208. The light-emitting layer 208 may be made of any of the materials having the properties as discussed above. Above the light-emitting layer 208, is lower transparent conducting electrode 206 and an upper transparent conducting electrode 202 that are above and below a switchable material layer 204, respectively. The electrodes 202, 206 may be a material such as indium tin oxide (ITO) or other transparent conductive oxides (TCOs). Additionally, one electrode, for instance the lower electrode 206 as depicted, may be a transparent material such as ITO, and the upper electrode 202 as depicted may be a reflective metal conductor, such as gold. In some applications, it may also be useful to electrically stimulate or excite the light-emitting layer 208. Additionally, a spacer layer (not depicted in FIG. 2) may be included between either the lower electrode 206 or the light-emitting layer 208. In other embodiments, the lower electrode 206 may be designed in such a way that it serves as a spacer layer.

By having the switchable material layer between the lower electrode 206 and the upper electrode 202 as depicted in FIG. 2, an electric field can be applied to the switchable material layer 204 causing the switchable material to switch states. By controlling the voltage differences between the two electrodes, the rate of switching can be controlled resulting in direct modulation of the light-emitting layer.

Other variations of electrical control are also available. For instance, in an embodiment, a resistive element is placed above the switchable material layer 204, rather than using the upper electrode 202 and the lower electrode 206 as depicted in FIG. 2. By passing current through the resistive element, the resistive element heats, causing the switchable material in the switchable material layer 204 to change state. By controlling the heating of the resistive element, the modulation of the light emission may be controlled. In another embodiment, electrodes in-plane with the switchable material may be used to run current through the switchable material.

In embodiments, the electrically controlled optical stack 200 may be implemented as a multilayer phosphor coating for a light emitting diode (LED). Where the light-emitting material is Er³⁺:Y₂O₃, the optical stack may be used in place of current erbium LEDs. Applying this technology to an LED provides a directly modulated erbium LED capable of optical communication. In addition to LEDs, the technology may be used as an up-converting phosphor, such as on a near-infrared silicon based camera. Additionally, this technology can be included in an integrated light emitting device for chip scale communication. For instance, the integrated light emitting device may include components on a semiconductor chip.

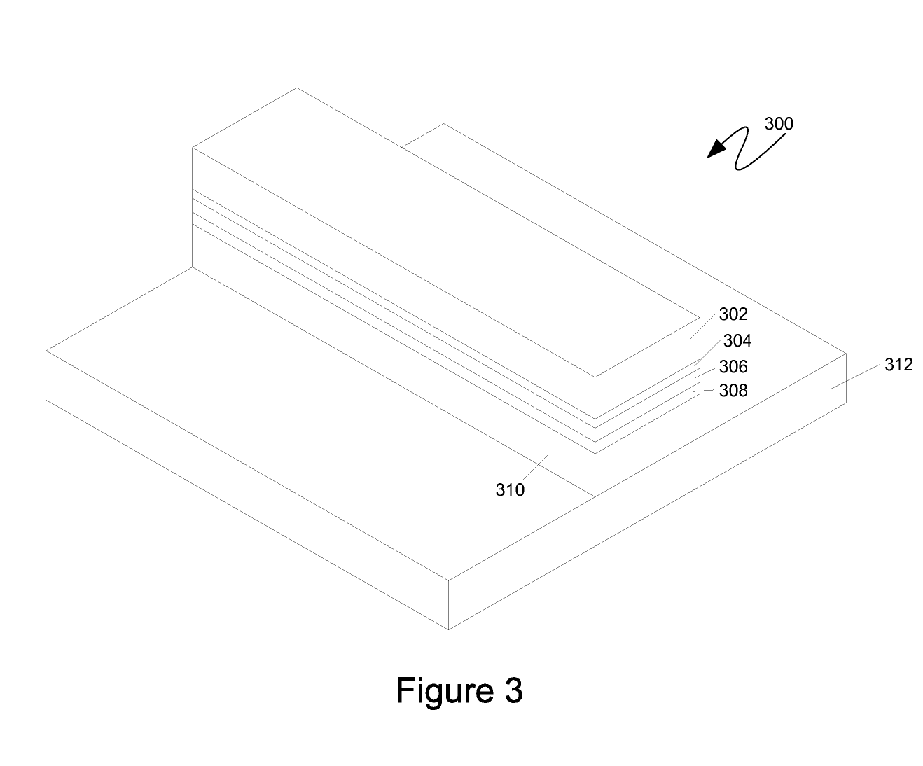

Other applications are also available, such as integrated optical components, including light-emitting waveguide structures. As depicted in FIG. 3, the technology may be implemented as a waveguide 300, such as a ridge or rib waveguide. As depicted in FIG. 3, in some embodiments, the waveguide 300 includes a base silicon-on-insulator (SOI) layer 312. Above the first silicon layer 310 is a light-emitting layer 308, such as the light-emitting layers discussed above. Above the light-emitting layer 308 is a spacer layer 306, and above the spacer layer is a switchable material layer 304. Above the switchable material layer 304 is another silicon layer 302.

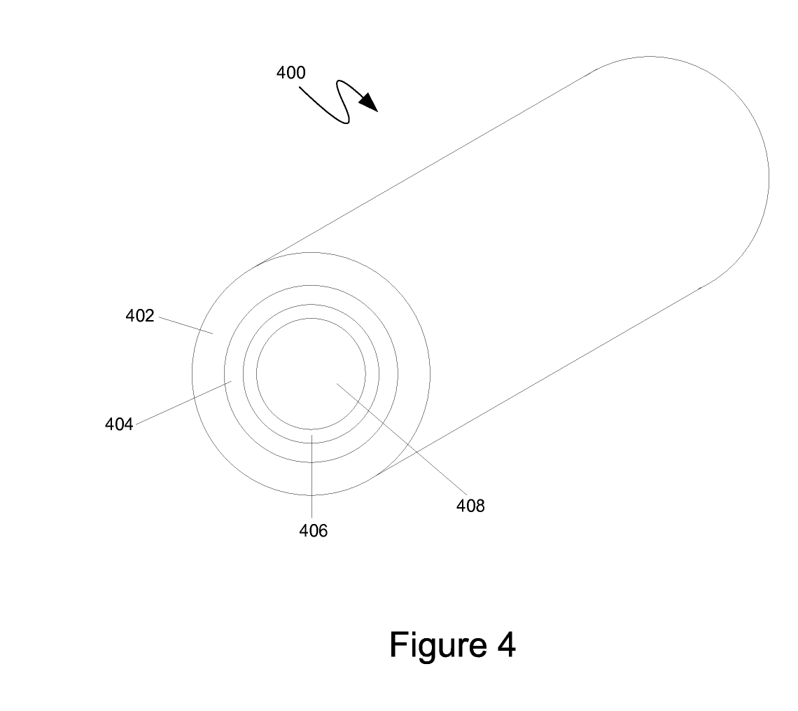

Another application for the technology, a multicomponent optical fiber 400, is depicted in FIG. 4. As shown in FIG. 4, the optical fiber 400 has an outer cladding layer 402. Internal to the cladding, there is a concentric layer of switchable material layer 404. Internal to the switchable material layer 404, there is a light-emission layer 406. There may also be a concentric spacer layer (not shown) between the light emission layer 406 and the switchable material layer 404. In the center of the multicomponent optical fiber 400 is a fiber 408 for carrying light signals. The fiber 408 may be made of silica, plastic, or other materials.

The figures depict the general structure and geometries of the technologies described herein. However, the figures have not been drawn to scale and it should be understood that the general shapes and geometries in the schematic figures may differ across various physical implementations. Although the subject matter has been described in language specific to the structural features and/or methodological acts it is to be understood that the subject matter defined in the appended claims is not necessarily limited to the specific features or acts described above. Rather, the specific features and acts described above are disclosed as examples for implementing the claims.

What is claimed is:

1. A multilayer thin film optical stack comprising:
a light-emitting layer; and
a switchable material layer, wherein light emission from the light-emitting layer is modulated based on the switchable material layer changing from a first state to a second state.

2. The multilayer thin film optical stack of claim 1, further comprising a spacer layer positioned above the light-emitting layer.

3. The multilayer thin film optical stack of claim 1, further comprising a reflective layer positioned above the switchable material layer.

4. The multilayer thin film optical stack of claim 1, further comprising a substrate layer positioned below the light-emitting layer.

5. The multilayer thin film optical stack of claim 1, wherein the light-emitting layer comprises one of the group consisting of: a lanthanide-emitter-doped glass host, a lanthanide-emitter-doped crystal host, a transition-metal-doped glass host, and a transition-metal-doped crystal host.

6. The multilayer thin film optical stack of claim 1, wherein the switchable material layer comprises vanadium dioxide (VO₂).

7. The multilayer thin film optical stack of claim 1, wherein light-emitting layer is about 10-100 nm thick and the switchable material layer is about 110-160 nm thick.

8. The multilayer thin film optical stack of claim 1, wherein the optical stack is capable of modulating light emitted from the light-emitting layer at least 1 GHz.

9. The multilayer thin film optical stack of claim 1, wherein the optical stack is substantially incorporated into a three-dimensional waveguide.

10. The multilayer thin film optical stack of claim 1, wherein the optical stack is substantially incorporated into a multicomponent optical fiber.

11. The multilayer thin film optical stack of claim 1, wherein the optical stack is substantially incorporated into a light-emitting diode.

12. The multilayer thin film optical stack of claim 1, further comprising one or more electrodes, wherein the one or more electrodes are configured to cause the switchable material to change phases.

13. The multilayer thin film optical stack of claim 1, wherein the light-emitting layer has a high magnetic local density of optical states (LDOS) when the switchable material layer is in an insulating state and high electric LDOS when the switchable material layer is in a metallic state.

14. The multilayer thin film optical stack of claim 1, wherein the light-emitting layer has a high electric local density of optical states (LDOS) when the switchable material layer is in an insulating state and high magnetic LDOS when the switchable material layer is in a metallic state.

15. A method of optical data transmission, the method comprising tuning an optical response of a switchable layer located adjacent a light-emitting layer, wherein light emitted from the light-emitting layer is modulated at a frequency higher than that of an inverse of the spontaneous emission rate of material comprising the light-emitting layer.

16. The method of claim 15, wherein the tuning is accomplished electrically.

17. The method of claim 15, wherein the tuning is accomplished optically.

18. The method of claim 15, wherein the tuning comprises causing a switchable material layer to change phase.

19. The method of claim 15, material comprising the light-emitting layer comprises erbium doped yttrium oxide (Er³⁺:Y₂O₃).

20. An apparatus comprising:
a light emitting erbium doped yttrium oxide (Er³⁺:Y₂O₃) layer, wherein the light emitting Er³⁺:Y₂O₃ layer is about 10-100 nm thick;
a spacer layer positioned above the light-emitting layer, wherein the spacer layer is about 80-100 nm thick;
a vanadium dioxide (VO₂) phase change layer positioned above the spacer layer, wherein the VO₂ phase change layer is about 110-160 nm thick; and
a reflective layer positioned above the VO₂ phase change layer, wherein light emission from the light emitting Er³⁺:Y₂O₃ layer is modulated based on the VO₂ phase change layer changing from a first state to a second state.
